(19) United States
(12) Patent Application Publication
(10) Pub. No.: US 2006/0084199 A1
(43) Pub. Date: Apr. 20, 2006

(54) Processing method during a package process

(75) Inventors: Chien Liu, Kaohsiung (TW); Meng-Jen Wang, Pingtung City (TW); Sheng-Tai Tsai, Kaohsiung (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/249,485

(22) Filed: Oct. 14, 2005

(30) Foreign Application Priority Data
Oct. 14, 2004 (TW) 93131187

(51) Int. Cl. H01L 21/50

(52) U.S. Cl. 438/106

(57) ABSTRACT

A processing method for preventing the lead fingers of a lead-frame from over-wetting and the conductive bumps from necking. After a flip chip is mounted to the lead fingers and before the reflowing process is conducted, the whole package structure is reversed so that conductive bumps are inclined to flow towards the chip during reflowing process.

This application claims the benefit of Taiwan application Serial No. 93131187, filed Oct. 14, 2004, the subject matter of which is incorporated herein by reference.

### BACKGROUND OF THE INVENTION

1. Field of the Invention

The invention relates in general to a processing method during a package process, and more particularly to a processing method during a flip-chip package process.

2. Description of the Related Art

The technology of flip-chip package process mainly includes the following steps. Firstly, an I/O bump is formed on a metallic pad on which a chip is disposed, and a contact point corresponding to the chip bump is formed on a substrate. Next the reversed chip is aligned to the contact point disposed on the substrate, and the chip is bonded to the I/O points on the substrate. With the features of excellent electric characteristics, high I/O contact point density and being able to reduce the size of IC and increase the output per wafer, the flip-chip package process has been recognized as a package method with great potential.

The standard manufacturing process of the flip-chip includes the processes of bumping and wafer sawing before assembly and the processes of chip bonding, reflowing, cleaning, underfilling, and curing during assembly. During assembly process, the chip is adhered onto the lead frame via epoxy, and then I/O solder points disposed on the chip are connected to the inner lead fingers disposed on the lead frame via an Au wire, and then the chip is sealed with resin lest the package might be damaged by an external force.

FIG. 1 is a side view of a chip reflowing process for a conventional flip-chip. Generally speaking, the chip 110 is reversed so that the surface on which the bumps 112 are disposed is face-down oriented to be mounted onto the lead fingers 114 of the lead frame (not shown in the diagram).

The lead frame is the main carrier of the IC package, and is made of the material such as copper alloy or iron-nickel alloy (Alloy-42). However, with the increase in the efficiency of the material of the bumps 112, problems arise in the interface between the bumps 112 and the lead fingers 114. One of the problems is that during reflowing, part of the material of the bumps 112 may be diffused to be spread over the lead fingers 114 due to the increase in fluidity or interaction with other interfaces. Consequently, necking might occur to the part of the bumps 112 in proximity to the surface of the lead fingers 114, deteriorating the reliability and efficiency of the whole package structure.

### SUMMARY OF THE INVENTION

According to the above disclosure, the efficiency may deteriorate when packing flip chips on a lead frame. It is therefore an object of the invention to provide a processing method during flip chip package, which prevents bumps from being diffused on the surface of lead fingers by the weight of the bumps during reflowing.

In order to prevent the bumps from necking, a processing method for packing flip-chip and lead frame is provided. When reflowing the bumps, the whole package structure is reversed, so that the surface of the flip chip on which the bumps are disposed is face-up oriented, and that the occurrences of bump necking are reduced due to the cohesive force of the bumps and the gravity of the flip chip.

The invention achieves the above-identified object by providing a processing method applied during a reflowing process. At first, a package structure is provided. The package structure includes at least a flip-chip, a number of conductive bumps and a lead frame mounted to each other. The flip-chip is connected to a number of conductive bumps via a solder pad surface, and the lead frame is connected to a number of conductive bumps via a conductive surface. Meanwhile, solder pad surface faces the same direction with the gravity. The package structure is reversed and then a reflow process is conducted so that the conductive bumps of the reversed package structure are bonded to the lead frame in a direction opposite to the gravity.

The invention achieves the above-identified object by further providing a processing method during package process. At first, a chip structure having a plurality of conductive bumps disposed on a solder pad surface is provided. Besides, a lead frame having a plurality of conductive lead fingers is provided. Then, the conductive bumps are mounted onto the conductive lead fingers and the solder pad surface faces the same direction with the gravity. The mounted chip structure and the lead frame are reversed so that the solder pad surface faces a direction opposite to the gravity. At last, a reflow process is conducted so that the conductive bumps of the reversed chip structure are bonded to the lead frame in a direction opposite to the gravity.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (PriorArt) is a side view of a chip reflowing process for a conventional flip-chip;

FIG. 2A is a side view of a chip bonding process according to a preferred embodiment of the invention;

FIG. 2B is a side view of the preferred embodiment of the invention before reflowing process.

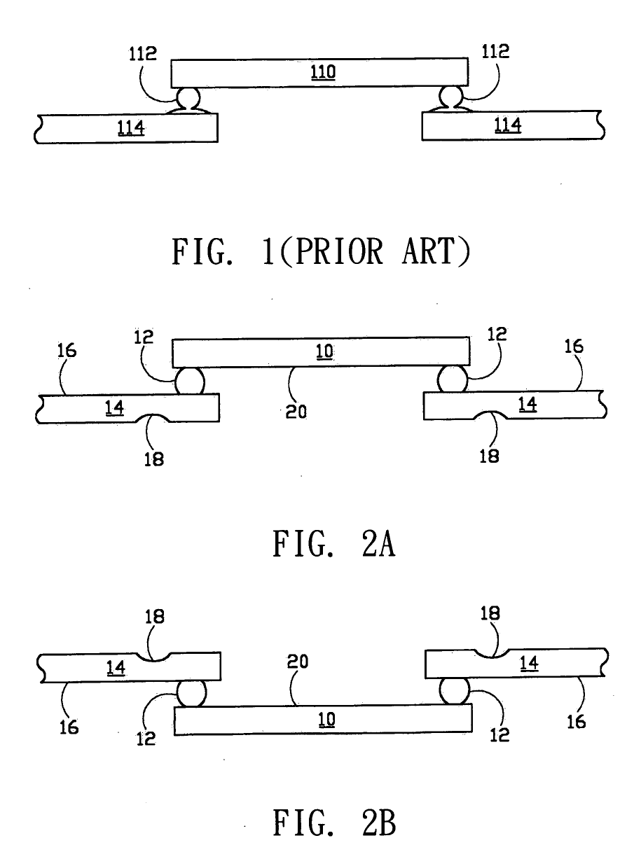

### DETAILED DESCRIPTION OF THE INVENTION

The embodiments of the invention are illustrated in accompany of drawings. During the elaboration of the embodiment of the invention, the part with respect to package structure is enlarged and explained. However, the scopes and interpretations of the invention are not to be limited thereto. Besides, in practical package structure and method, other necessary parts of the package structure should be included therein.

Next, the device or structure in the drawings of the embodiments of the invention may be exemplified by only one device or structure. However, the scopes and interpretations of the invention are not to be limited thereto, and when the number of devices or structures is not specified in the exemplification disclosed below, both the singular number and plural number are applicable according to the spirit and scope of application of the invention.

FIG. 2A is a side view of a chip bonding process according to a preferred embodiment of the invention. Referring to FIG. 2A, in the step of mounting the chip 10 onto the lead fingers 14 of the lead frame (not shown in the diagram), the chip 10 is reversed so that the surface on which the bumps 12 are disposed is face-down oriented to be mounted onto a conductive surface 16 of the lead fingers 14. In the preferred embodiment, the chip 10 is a die, and can be any chip which needs to be packaged, such as a semiconductor component, a photo-sensing component or an optoelectric component for instance. The bump 12 can be a solder bump, a gold bump or a non-tin solder bump. It is noteworthy that a conductive structure (not shown in the diagram) such as an under bump metallurgy (UBM) is formed between the chip 10 and the bump 12.

The lead fingers 14, which use copper alloy or iron-nickel alloy as the main material, are bonded to the bumps 12 via the conductive surface 16 disposed at the terminal end of the lead fingers. The preferred embodiment further uses a dispenser to dispense an ordinary adhesive on the part of the conductive surface 16 of the lead fingers 14 corresponding to the positions or the peripherals of the bumps 12 to form an adhesive structure which forms a subsequent corner bond but is not limited thereto. Besides, the lead fingers 14 can be geometrically shaped. For example, the lead fingers 14 can have notches 18 but are not limited thereto.

During the mounting process, the surface on which the lead frame having lead fingers 14 are mounted is face-up oriented, that is, faces an opposite direction of the gravity. On the other hand, the chip 10 on which the bumps 12 are mounted is face-down oriented, that is, the chip 10 faces the same direction with the gravity so as to adhere the bumps onto the lead fingers. In the preferred embodiment, the bumps and the lead fingers are adhered and mounted through a pre-curing step to form the abovementioned corner bond.

Referring to FIG. 2B, a side view of the preferred embodiment of the invention before reflowing process is shown. The whole structure of the above mounting step is reversed first before the reflowing process is conducted. When the whole structure is reversed, the chip 10 becomes the bottom most component of the whole structure. The surface of solder pad 20 on which the bumps 12 are disposed is face-up oriented, that is, an opposite direction of the gravity. On the other hand, the conductive surface 16 of the lead fingers 14 on which the bumps 12 are mounted is face-down oriented, that is, the same direction with the gravity. During reflowing, the increase in temperature boosts the fluidity of material of the bumps 12. Meanwhile, the bumps 12 with higher fluidity would gather towards the surface of the chip 10 due to cohesive force and gravity. Ascribed to the existence and geometrical shape of the under bump metallurgy, the bumps 12 with a higher fluidity is curbed and would not be over-diffused. On the other hand, the bumps 12 are prevented from being diffused on the conductive surface 16 of the lead fingers 14, thereby preventing the part of the bumps 12 in proximity to the interface from necking.

In the processing method during package process according to a preferred embodiment of the invention, firstly, a chip structure and a lead frame are provided. The chip structure has a number of conductive bumps, such as solder bumps or gold bumps for instance, disposed on a solder pad surface. The lead frame, using iron/nickel or copper as the main material, includes a number of conductive lead fingers. Afterwards, the conductive bumps are pre-cured to be mounted onto the conductive lead fingers. The solder pad surface 20 faces the same direction with the gravity. Next, the mounted chip structure and lead frame are reversed, so that the solder pad surface 20 faces a direction opposite to the gravity. Afterwards, a reflow process is conducted so that the conductive bumps of the reversed chip structure are bonded the lead frame in a direction opposite to the gravity.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A processing method during package process, comprising:
providing a chip structure having a plurality of conductive bumps disposed on a solder pad surface;
providing a lead frame having a plurality of conductive lead fingers;
mounting the conductive bumps onto the conductive lead fingers, wherein the solder pad surface faces the same direction with the gravity;
reversing the mounted chip structure and the lead frame, so that the solder pad surface faces a direction opposite to the gravity; and
conducting a reflow process so that the conductive bumps of the reversed chip structure are bonded to the lead frame in a direction opposite to the gravity.

2. The processing method during package process according to claim 1, wherein the step of providing the chip structure comprises providing a plurality of solder bumps as the conductive bumps.

3. The processing method during package process according to claim 1, wherein the step of providing the chip structure comprises providing a plurality of gold bumps as the conductive bumps.

4. The processing method during package process according to claim 1, wherein the step of providing the lead frame comprises providing a lead frame whose main material is iron/nickel.

5. The processing method during package process according to claim 1, wherein the mounting step comprises pre-curing the conductive bumps.

6. The processing method during package process according to claim 1, wherein the mounting step comprises forming a plurality of adhesive structures by dispensing and pre-curing the conductive bumps on each of the conductive lead fingers.
